(19) United States
(12) Patent Application Publication
(10) Pub. No.: US 2009/0255571 A1
(43) Pub. Date: Oct. 15, 2009

(54) Thermal Conducting Materials for Solar Panel Components

(75) Inventors: Zhiyong Xia, Rockville, MD (US); Daniel W. Cunningham, Mount Airy, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 12/327,246

(22) Filed: Dec. 3, 2008

Related U.S. Application Data
(60) Provisional application No. 61/044,618, filed on Apr. 14, 2008.

(51) Int. Cl. H01L 31/048; H01L 31/00; B29C 65/02

(52) U.S. Cl. 136/251; 136/259; 156/286

(57) ABSTRACT

This invention relates to solar panels with improved encapsulants and backsheets for greater power output and/or increased efficiency by using materials with higher thermal conductivity than conventional solar panels. According to certain embodiments the improved materials include fillers while maintaining sufficient dielectric properties. According to certain other embodiments, the invention includes a solar panel with the improved encapsulant between solar cells and the improved backsheet. The invention also includes a method of making a solar panel including the improved materials.

### RELATED APPLICATIONS

This application claims the benefit of priority from U.S. Provisional Application No. 61/044,618, filed Apr. 14, 2008, which is expressly incorporated herein by reference in its entirety.

### BACKGROUND

1. Field of the Invention

This invention relates to the use of higher thermal conducting materials in solar panels and solar modules for improved efficiency, greater power output, and/or reduced operating temperatures.

2. Discussion of Related Art

Conventional photovoltaic collectors or solar devices typically include a plurality of solar cells disposed between a glass substrate and a rear electrically insulating material. An encapsulant is used to bind the glass substrate, the solar cells and the rear electrically insulating material together. Conventional solar devices utilize unfilled encapsulants for lamination.

Generally, solar devices lose about 0.4 percent to about 0.5 percent in power for each additional 1 degree Celsius of operating temperature. Typically, solar devices are placed in full direct sunlight and as such operate at temperatures above their surroundings due to inefficiencies of conversion and absorption of solar radiation. Undesirably, these increased operating temperatures of the solar device can significantly reduce the electrical power output.

There is a need and a desire for solar devices that operate with a greater power output and/or a higher efficiency by lowering an operating temperature of the solar device through conducting and/or dissipating temperature and/or heat across back or bottom materials.

### SUMMARY

One aspect of this invention is to use higher thermal conducting materials and/or packaging in the solar panels and solar modules for greater power output, improved efficiency, and/or reduced operating temperatures by transferring heat to the surroundings across and/or through the back or bottom materials and/or layers. There is a need for encapsulants and/or backsheets used in solar panels with higher thermal conductivities than conventional materials, while maintaining sufficient dielectric properties for reliable operation.

These and other aspects of this invention are accomplished at least in part with a photovoltaic or semiconductor encapsulant including an encapsulant polymeric material and an encapsulant filler material, wherein the encapsulant has a thermal conductivity of about at least 0.26 watt per meter per Kelvin and a dielectric constant of about at least 2.0 measured at 60 hertz.

This invention also includes a photovoltaic or semiconductor backsheet with a backsheet polymeric material and a backsheet filler material, wherein the backsheet has a dielectric constant of about at least 2.0 measured at 60 hertz and a higher thermal conductivity than the backsheet polymeric material in neat form.

This invention further includes a solar panel with a front layer and at least one photovoltaic cell having the front layer disposed with respect to a front side of the at least one photovoltaic cell, an encapsulant contacting at least a portion of a back side of the at least one photovoltaic cell and disposed at least partially between the at least one photovoltaic cell and a backsheet. The encapsulant includes a first polymeric material and a first thermal conducting filler material, so the encapsulant has a thermal conductivity of about at least 0.26 watt per meter per Kelvin and a dielectric constant of about at least 2.0 measured at 60 hertz.

This invention further includes a process for making a solar panel including the steps of providing a front layer, placing a first sheet of encapsulant material over at least a portion of the front layer, placing at least one photovoltaic cell over the first sheet of encapsulant material, placing a second sheet of encapsulant material over the at least one photovoltaic cell. The second sheet of encapsulant material includes a first polymeric material and a first filler material and the second sheet of encapsulant material having a thermal conductivity of about at least 0.26 watt per meter per Kelvin and a dielectric constant of about at least 2.0 measured at 60 hertz.

The method also includes the step of placing a backsheet over the second sheet of encapsulant material. The backsheet includes a second polymeric material and a second filler material, the backsheet having a dielectric constant of about at least 2.0 and a higher thermal conductivity than the second polymeric material in neat form. The method also includes the step of laminating the solar panel for a sufficient time and a sufficient temperature for sufficient crosslinking of the first sheet and/or the second sheet.

### BRIEF DESCRIPTION OF THE DRAWINGS

The above and other features and aspects of this invention are better understood from the following detailed description taken in view of the drawings wherein:

FIG. 1 is a cross sectional exploded schematic view of a solar panel, according to one embodiment;

FIG. 2 is a graph of thermal conductivity, according to one embodiment;

FIG. 3 is a graph of gas permeability, according to one embodiment;

FIG. 4 is a graph of temperature differences between a reference panel and a panel with a filled encapsulant, according to one embodiment;

FIG. 5 is a graph of temperature differences between a reference panel and a panel with a filled encapsulant, according to one embodiment;

FIG. 6 is a graph of temperature differences and power differences between a reference panel and a panel with a filled encapsulant, according to one embodiment; and

FIG. 7 is a graph of temperature differences and power differences between a reference panel and a panel with a filled encapsulant, according to one embodiment.

### DETAILED DESCRIPTION

As used herein, the term “encapsulant” broadly, without limitation, includes compounds or materials useful for laminating, adhering, adjoining, gluing, sealing, caulking and/or joining at least a portion of components of a semiconductor, a solar panel, a solar module, a solar array and/or any other suitable assembly.

As used herein, the term “backsheet” broadly, without limitation, includes compounds or materials useful for at least a portion of a layer or a cover on a side opposite a sun facing side of a semiconductor, a solar panel, a solar module, a solar array and/or any other suitable assembly. Desirably, the backsheet includes dielectric properties, such as, for example, to prevent short circuiting and/or allow reliable operation of a device.

As used herein, the term “thermal conductivity” broadly, without limitation, includes a material property to conduct and/or transfer heat or thermal energy. Thermal conductivity typically has units of watt per meter per Kelvin or sometimes referred to as watt per meter-Kelvin or w/m*K. According to certain embodiments, thermal conductivity in the range from 0.1 watt per meter per Kelvin to 60 watt per meter per Kelvin at 30 degrees Celsius is measured according to ASTM E1530-04 “Standard Test Method for Evaluating the Resistance to Thermal Transmission of Materials by the Guarded Heat Flow Meter Technique”. According to other embodiments, thermal conductivity is measured at room temperature, ambient temperature, solar panel operating temperature, about 23 degrees Celsius and/or any other suitable temperature. Thermal conductivity of materials directly affects an ability of a material to transfer or dissipate thermal energy, such as an increase in thermal conductivity produces an increase in thermal transfer.

As used herein, the term “dielectric constant” or sometimes referred to as “relative static permittivity”, “relative dielectric constant” and/or “static dielectric constant” includes broadly, without limitation, a material property under a given condition to concentrate electrostatic lines of flux. Dielectric constant is a dimensionless number or one without units. According to certain embodiments, dielectric constant is measured according to the method described in ASTM D150-98 “Standard Test Methods for AC Loss Characteristics and Permittivity (Dielectric Constant) of Solid Electrical Insulation”.

As used herein, the term “D50” particle size includes the median diameter, where 50 percent of the volume is composed of particles larger than the stated D50, and 50 percent of the volume is composed of particles smaller than the stated D50 value.

As used herein, the term “thermal diffusivity” or sometimes referred to as “α” is measured in meters squared per second and calculated with the following equation:

$$α = \frac{K}{ρ {C}_{p}}$$

Where, the term “K” refers to thermal conductivity in watt per meter per Kelvin, as described above. The term “Cₚ” refers to specific heat as measured in joules per kilogram per Kelvin, and the term “ρ” refers to density as measured in grams per centimeter cubed. Thermal diffusivity may include any suitable value and broadly includes the ability of a material to conduct heat relative to storing heat. Physically, a material with a higher thermal diffusivity indicates it has greater capabilities of conducting heat than storing heat, for example. According to one embodiment, suitable thermal diffusivity ranges from about 1.0×10⁻⁴ to about 1.0×10⁻⁷ meters squared per second, preferably about 1.0×10⁻⁵ to about 10×10⁻⁶ meters squared per second and more preferably at least about 1.3×10⁻⁷ meters squared per second.

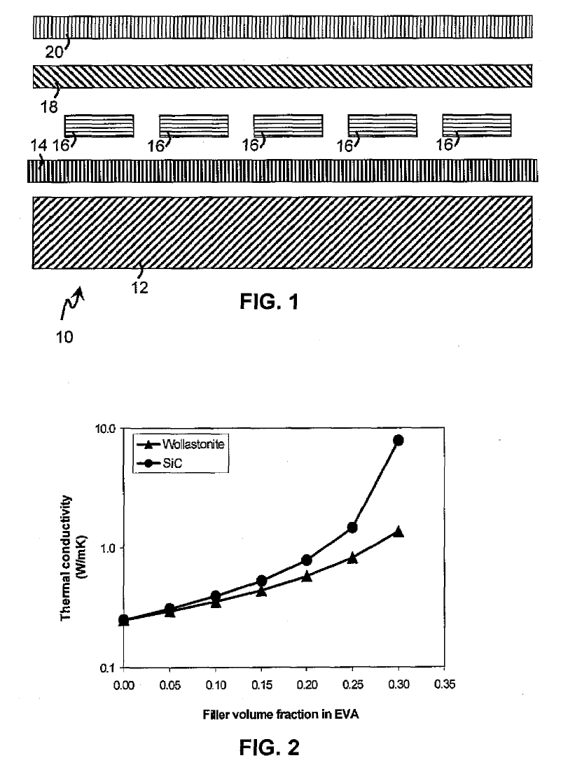

As schematically shown in cross sectional exploded view of FIG. 1 and according to one embodiment, a solar panel 10 includes one or more photovoltaic cells 16 disposed between a front layer 12 and a backsheet 20. Desirably, the backsheet 20 includes increased thermal conductivity versus a conventional solar device. A first encapsulant sheet 14 desirably includes good optical properties and laminates a front side of the photovoltaic cells 16 with respect to the front layer 12. A second encapsulant sheet 18 desirably includes increased thermal conductivity and laminates a back side of the photovoltaic cells 16 with respect to the backsheet 20.

The elements of FIG. 1 are not necessarily drawn to scale and are not limiting to the embodiments of this invention. Assembled solar panels desirably include laminated intimate thermal and/or physical contact between and/or among components.

According to one embodiment, this invention includes a photovoltaic or semiconductor encapsulant including a polymeric material and a filler material, wherein the encapsulant has a thermal conductivity of about at least 0.26 watt per meter per Kelvin and a dielectric constant of about at least 2.0 measured at 60 hertz.

Polymeric material broadly includes any suitable natural, synthetic and/or combination of relatively high molecular weight compound, typically, but not necessarily, including one or more repeating units. Types of polymeric materials include the following and combinations of the following:
(1) polyolefins, such as polyethylene, polypropylene, ethylene and propylene copolymer, polyethylene ionomer, ethylene and ethylene vinyl acetate copolymer, crosslinked polyethylene and the like;
(2) polyesters, such as polyethylene terephthalate, polyethylene naphthalate, polytrimethylene terephthalate, polybutylene terephthalate, polycarbonate and the like;
(3) polyamides, such as nylon and the like;
(4) acrylates, such as polymethyl methacrylate, polymethyl acrylate and the like;
(5) elastomers, such as thermoplastic polyurethane, polybutadiene, silicone, polyisoprene, natural rubber and the like;
(6) fluoropolymers, such as polyvinylidene fluoride, polyvinyl fluoride, polytetrafluoroethylene and the like;
(7) biodegrdable polymers, such as polylactic acid, polyhydroxybutyrate, polyhydroxyalkanoate and the like;
(8) vinyl polymers, such as polyvinyl chloride, polyvinyl acetate, polystyrene and the like; and
(9) others, such as miscellaneous thermoplastic resin, thermoset resin, plastomer and/or any other suitable chain-like molecule.

Combinations as used herein broadly refers to any polymer in any suitable amount selected from the disclosure combined with one or more other polymers each in any suitable amount from the disclosure. Desirably, the polymeric material includes suitable thermal and/or dielectric properties.

According to one embodiment, the encapsulant also includes a lower heat capacity than an unfilled and/or neat encapsulant. Heat capacity includes the amount of thermal energy needed to raise a temperature of a substance and may be measured as joules per degree Kelvin, for example. According to certain embodiments, heat capacity is measured by ASTM E1269-05 “Standard Test Method for Determining Specific Heat Capacity by Differential Scanning Calorimetry”.

According to one embodiment, the polymeric material of the encapsulant includes a copolymer of ethylene and vinyl acetate in any suitable ratio, such as, for example, about 4 percent to about 90 percent vinyl acetate by weight, preferably about 20 percent to about 60 percent vinyl acetate by weight and more preferably about 33 percent vinyl acetate by weight. The ethylene vinyl acetate may include any suitable molecular weight and/or viscosity, such as, for example, a melt flow index of about 5 to about 40 grams per 10 minutes, preferably about 10 to about 20 grams per 10 minutes and more preferably about 15 grams per 10 minutes. Neat or pure ethylene vinyl acetate includes a thermal conductivity of about 0.20 watt per meter per Kelvin and a heat capacity of about 2.27 joule per gram Kelvin measured at 25° C. Silicon, such as used in solar cells includes a thermal conductivity of about 153 watt per meter per Kelvin and a heat capacity of about 0.71 joule per gram Kelvin.

Filler material broadly includes any suitable natural, synthetic and/or combination of a substance at least partially differing from the polymeric material. Filler materials may include, for example, minerals, fibers, metallic compounds and/or any other suitable items. According to one embodiment, the filler material of the encapsulant includes glass fiber, such as, for example, woven glass fiber, nonwoven glass fiber, glass matting, glass scrim, bulk glass fiber, staple glass fiber and/or any other suitable silicon based material. Glass fibers may include any suitable diameter, such as, for example, about 1 micrometer to about 100 micrometers, preferably about 5 micrometers to about 20 micrometers and more preferably about 6.5 micrometers.

According to another embodiment, the filler material of the encapsulant includes calcium carbonate (thermal conductivity of 3.59 watt per meter per Kelvin), calcium silicate, talc, barite, barium sulfate (thermal conductivity of 1.31 watt per meter per Kelvin), clay, metal compound, semimetal compound, rutile titanium oxide (thermal conductivity of 5.12 watt per meter per Kelvin), anatase titanium oxide, magnetite (thermal conductivity of 5.1 watt per meter per Kelvin), alumina (thermal conductivity of 30 watt per meter per Kelvin), silicon dioxide (thermal conductivity of 7.6 watt per meter per Kelvin), aluminum nitride (thermal conductivity of 100 watt per meter per Kelvin), wollastonite (thermal conductivity of 2.5 watt per meter per Kelvin) and/or silicon carbide (thermal conductivity of 120 watt per meter per Kelvin), for example. Desirably, filler materials provide additional structural integrity and/or assist in manufacture of the solar panel.

As shown in FIG. 2 and according to an embodiment, the effect of filler material (wollastonite and silicon carbide) content greatly increases thermal conductivity of ethylene vinyl acetate For example, the addition of 5 percent by volume wollastonite and silicon carbide improves thermal conductivity of the composite ethylene vinyl acetate by 18 percent and 23 percent respectively. The addition of 10 percent by volume wollastonite and silicon carbide improves thermal conductivity of the composite ethylene vinyl acetate by 42 percent and 57 percent respectively. As discussed above, these increases in thermal conductivity allow dissipation of heat from the solar panel through the back and/or bottom to lower operating temperatures and thus increase power output and/or efficiency of the solar panel. Additional increases in thermal conductivity of 10 fold and surprisingly even almost 30 fold are possible at higher levels of filler material, as shown in FIG. 2, for example.

Filler material may include any suitable size and/or shape. According to one embodiment, the filler material includes an equivalent average particle size or “D50”, such as, for example, from about 0.001 micrometers to about 1000 micrometers, preferably about 0.1 micrometers to about 250 micrometers and more preferably about 0.2 micrometers to about 50 micrometers and even more preferably from about 0.2 micrometers to about 2.0 micrometers. Suitable equivalent average particle size measuring methods include microscopy techniques and/or sedimentation analysis, such as calculating an average particle size or D50, for example.

Filler material may include any suitable thermal conductivity, such as, for example, at least about 1 watt per meter per Kelvin, preferably at least about 5 watt per meter per Kelvin and more preferably at least about 100 watt per meter per Kelvin.

According to one embodiment, the filler material includes an aspect ratio of its longest dimension to its shortest dimension, such as, for example, of equal to or greater than about 1.0, preferably greater than about 10 and more preferably greater than about 50 and even more preferably greater than about 100. Aspect ratio is a dimensionless number.

Filler material may include any suitable specific gravity, such as, for example, about 0.1 to about 10 and preferably about 1 to about 5. Specific gravity includes a ratio of a density of a substance to a density of water and is a dimensionless number. According to an embodiment, specific gravity can be measured by ASTM D792-00 “standard Test Methods for Density and Specific Gravity (Relative Density) of Plastics by Displacement”.

The encapsulant may include any suitable amount of filler material on a mass or a volume basis, such as, for example, about 0.1 volume percent to about 30 volume percent, preferably about 2 volume percent to about 15 volume percent and more preferably about 4 volume percent to about 6 volume percent. Desirably, the filler material remains evenly dispersed and/or distributed within the encapsulant in a single at least relatively homogeneous phase.

The thermal conductivity of the encapsulant material may include any suitable value, such as, for example, at least 0.15 watt per meter per Kelvin, preferably at least 0.2 watt per meter per Kelvin, preferably at least 0.26 watt per meter per Kelvin and more preferably at least about 0.3 watt per meter per Kelvin. According to another embodiment, the thermal conductivity of the encapsulant includes at least about 0.5 watt per meter per Kelvin, alternately at least about 0.75 watt per meter per Kelvin, alternately at least about 1.0 watt per meter per Kelvin, alternately at least about 2.0 watt per meter per Kelvin, alternately at least about 3.0 watt per meter per Kelvin, alternately at least about 5.0 watt per meter per Kelvin, alternately at least about 7.5 watt per meter per Kelvin and alternately at least about 10 watt per meter per Kelvin.

The dielectric constant measured at 60 hertz of the encapsulant material may include any suitable value, such as, for example, about 0.5 to about 30, preferably about 1 to about 10, more preferably about 2 to about 5 and more preferably at least about 2.0.

The encapsulant of this invention may further include any other additional material and/or compound, such as, for example, chemical cross linking agents, adhesion promoters, stabilizers, coupling agents, surfactants, ultraviolet inhibitors, ultraviolet absorbers, antioxidants, coagents, and/or any other suitable materials. According to one embodiment, a suitable chemical cross linking agent or thermosetting activator includes peroxides and a suitable antioxidant includes butylated hydroxytoluene and/or other non-phenolic type antioxidants.

According to one embodiment, the encapsulant includes at least one silane coupling agent for dispersing the filler material in the polymeric material and/or promoting adhesion, for example. Desirably, the at least one silane coupling agent includes a first functionality or reactivity type, such as, for example, amino groups, epoxy groups, phenyl groups, vinyl groups, alkyl groups and/or any other suitable chemical groups, and includes a second functionality or reactivity type, such as, for example, methoxy reactivity groups, ethoxy reactivity groups and/or any other suitable chemical groups. According to one embodiment, the first functionality reacts with organic molecules and the second functionality reacts with inorganic molecules.

Ingredients or components of the encapsulant may be processed by various types of equipment, such as, for example, dry blenders, kneading rolls, extruders, casting equipment, blowing equipment, molding equipment and/or any other suitable compounding machinery or implements.

According to one embodiment, the encapsulant may be formed into pellets, such as, for example, to enable or facilitate additional processing or use. According to another embodiment, the encapsulant may be formed into sheets or films, such as, for example to enable or facilitate additional processing or use. According to yet another embodiment, the encapsulant may be formed over or in combination with glass matting, such as, for example, to enable or facilitate additional processing or use.

Sheets and/or films may include any suitable thickness, such as, for example, about 0.5 micrometers to about 5000 micrometers, about 10 micrometers to about 2000 micrometers, preferably about 10 micrometers to about 1000 micrometers and more preferably about 10 micrometers to 500 micrometers. Sheets and/or films include dimensions having a high aspect ratio and/or a generally planar or flat configuration.

According to one embodiment, the encapsulant includes good optical properties, such as, having a refractive index and clarity similar to clear glass. An encapsulant with good optical properties may be used between the glass and a front side of a solar cell and/or between a back side of a solar cell and a backsheet. According to another embodiment, the encapsulant includes fair optical properties, such as, having a translucent, frosted, cloudy and/or hazy appearance. An encapsulant with fair optical properties desirably may be used between the back of the photo cells and the backsheet. According to yet another embodiment, the encapsulant includes poor optical properties, such as, having an opaque and/or solid appearance. An encapsulant with poor optical properties desirably may be used between the back of the photo cells and the backsheet.

According to one embodiment, the terms “between the back side of the solar cell and the backsheet” include surrounding at least a portion of a lateral side or portion of the solar cell, but not covering a front side or portion of the solar cell. Desirably, a front or first sheet of encapsulant with at least good optical properties may be placed or disposed between the glass and the front side of the solar cells to bond and/or join areas between solar cells with a second sheet of encapsulant placed or disposed between a backside of the solar cells and the backsheet. Even more desirably, the solar cells are completely sandwiched between layers of encapsulant.

According to one embodiment, this invention further includes a photovoltaic or semiconductor backsheet or back cover including a polymeric material and a filler material, wherein the backsheet has a dielectric constant of about at least 2.0 measured at 60 hertz and a higher thermal conductivity than the polymeric material in neat form.

The term “neat” or “neat form” refers to being free from additional matter The term “virgin” may also refer to being free from additional matter and usually includes materials not previously processed. The remarks above regarding encapsulants generally apply to the backsheet, such as, thermal conductivity, heat capacity, polymeric materials, filler materials, additives and the like. Desirably, the backsheet provides waterproof and/or weatherproof protection for the solar panel. Polyethylene terephthalate includes a thermal conductivity of about 0.15 watt per meter per Kelvin and a heat capacity of about 1.17 joule per gram Kelvin.

According to one embodiment, the polymeric material of the backsheet includes polypropylene, polyethylene terephthalate, polyvinyl fluoride, polyvinylidene fluoride and/or any other suitable plastic material. The backsheet may include one or more composite or laminate layers. The backsheet may include any number of layers, such as, for example, 1, 2, 3, 4, 6, 8 and/or any other suitable number.

According to another embodiment, the backsheet includes additional laminate layers, such as, for example, polyester, aluminum, copper, steel, glass, polyvinyl fluoride, polyvinylidene fluoride, polytetrafluoroethylene and/or any other suitable substance.

According to one embodiment, the dielectric constant of the composite backsheet desirably is at least 2.0 measured at 60 hertz, but individual layers and/or components of the backsheet may themselves be electrical conductors without compromising the integrity, operability and/or efficiency of the solar panel, for example. According to another embodiment, the backsheet includes a multilayer material, such as, for example, polyvinyl fluoride-polyester-polyvinyl fluoride, polyvinyl fluoride-aluminum-polyvinyl fluoride, polyvinyl fluoride-aluminum-polyester and/or any other suitable combination of substances.

Generally, but not necessarily, the backsheet includes poor optical properties and may further include colorants, pigments and/or any other suitable additional substances.

According to one embodiment, the backsheet may include a glass sheet or other suitable relatively stiff material. A glass backsheet may include the same or different materials as the front sheet. According to one embodiment, the glass backsheet includes soda-lime glass, borosilicate glass and/or any other suitable material. Desirably, but not necessarily, the glass backsheet includes a higher thermal conductivity than the front sheet, such as, for example, by including additional fillers and/or coatings. Suitable fillers or coatings may include metals, polymers, minerals and/or any other material or substance improving the thermal conducting properties of the backsheet. According to one embodiment, the glass backsheet includes a thermal conductivity of at least about 1.4 watt per meter per Kelvin.

According to another embodiment and depending on the solar cell technology, the solar panel desirably, but not necessarily, includes a layer of encapsulant material between the solar cell and the glass backsheet.

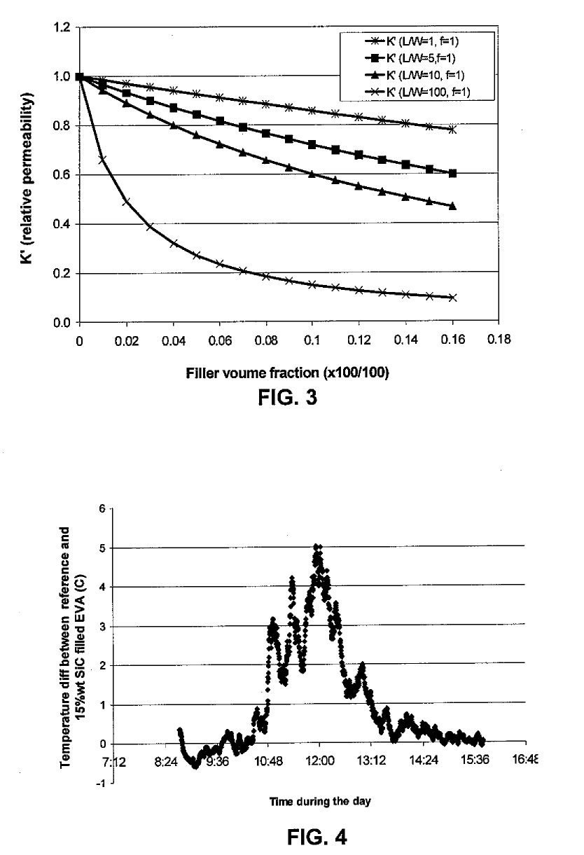

The filled backsheet of this invention desirably forms a tortuous path to reduce moisture and/or vapor permeability. Moisture permeation through the backsheet can increase corrosion, increase short circuiting, reduce operating efficiency and/or shorten useful life of a solar panel. A tortuous path through the backsheet desirably can reduce the likelihood of moisture and/or reliability related issues. As shown in FIG. 3 and according to one embodiment, the reduction of gas permeability, particularly for high aspect sheet-like fillers, can be significant, such as a reduction of over about 20 percent, over about 40 percent, over about 50 percent and even over about 80 percent. Sheet-like fillers may include, for example, clay, nanoclay, talc and/or any other suitable substance.

According to one embodiment, the backsheet includes a filler material of calcium carbonate, calcium silicate, talc, barite, clay, rutile titanium oxide, anatase titanium oxide, magnetite, alumina, silicon dioxide, aluminum nitride, boron nitride, silicon carbide and/or any other suitable substance.

According to one embodiment, this invention further includes a solar panel with a front layer and at least one photovoltaic cell. The solar panel may include the front layer disposed with respect to a front side of the at least one photovoltaic cell, an encapsulant contacting at least a portion of a back side of the at least one photovoltaic cell and disposed at least partially between the at least one photovoltaic cell and a backsheet. The encapsulant includes a first polymeric material and a first thermal conducting filler material having a thermal conductivity of about at least 0.26 watt per meter per Kelvin and a dielectric constant of about at least 2.0 measured at 60 hertz.

According to one embodiment, the solar panel further includes the backsheet with a second polymeric material and a second thermal conducting filler material, the backsheet having a dielectric constant of about at least 2.0 measured at 60 hertz and a higher thermal conductivity than the second polymeric material in neat form. According to another embodiment, the backsheet includes a glass sheet.

The front layer or sheet includes any suitable material transmissive with respect to at least a portion of ultraviolet light, visible light and/or infrared light. According to one embodiment, the front sheet includes glass, soda-lime glass, borosilicate glass, tempered glass, polycarbonate and/or any other suitable material. According to another embodiment, the front sheet includes an anti-reflection coating, such as, for example, amorphous silicon and/or any other suitable material.

The photovoltaic cell and/or solar cell includes any suitable material for capturing and/or converting at least a portion of ultraviolet light, visible light and/or infrared light desirably to electricity, such as, but not limited, to, a silicon wafer.

According to one embodiment of the solar panel, the first polymeric material comprises a copolymer of ethylene and ethylene vinyl acetate, and the second polymeric material comprises polyethylene terephthalate. According to a further embodiment, the ethylene vinyl acetate comprises a copolymer of ethylene and vinyl acetate having about 4 percent to about 90 percent by weight vinyl acetate and a melt flow index of about 5 to about 40 grams per 10 minutes.

According to one embodiment of the solar panel, the first polymeric material is the same as the second polymeric material. According to another embodiment of the solar panel, the first polymeric material differs from the second polymeric material.

According to one embodiment of the solar panel, the first thermal conducting filler material is the same as the second thermal conducting filler material. According to another embodiment of the solar panel, the first thermal conducting filler material differs from the second thermal conducting material.

According to another embodiment, the solar panel further includes at least one solar concentrator and/or intensifier, such as, for example, a lens, a Fresnel lens, a convex lens, a concave lens, a compound lens, a reflector and/or any other suitable device to improve or increase power output and/or solar efficiency. The solar concentrator desirably, but not necessarily, may be positioned on, above and/or adjacent to the front layer. According to an embodiment, the solar concentrator replaces the front layer. Concentrated and/or intensified solar panels may have increased operating temperatures and further benefit from the higher thermal conducting materials of this invention, for example.

This invention also includes a method of making a solar panel including the steps of providing a front layer, placing a first sheet of encapsulant material over at least a portion of the front layer, placing at least one photovoltaic cell over the first sheet of encapsulant material, placing a second sheet of encapsulant material over the at least one photovoltaic cell, the second sheet of encapsulant material comprising a first polymeric material and a first filler material, the second sheet of encapsulant material having a thermal conductivity of about at least 0.26 watt per meter per Kelvin and a dielectric constant of about at least 2.0 measured at 60 hertz.

The method of making a solar panel further includes the steps of placing a backsheet over the second sheet of encapsulant material, the backsheet comprising a second polymeric material and a second filler material, the backsheet having a dielectric constant of about at least 2.0 and a higher thermal conductivity than the second polymeric material in neat form, and laminating the solar panel for a sufficient time and a sufficient temperature for sufficient crosslinking of the first sheet and/or the second sheet.

The order of the above described steps recites a possible sequence of the steps, but should not be construed as limiting in any manner. The relative physical arrangement of items described above recites a possible configuration, but should not be construed as limiting in any manner.

Laminating the solar panel for a sufficient time and/or a sufficient temperature for a sufficient lamination includes crosslinking of an organic component of at least a portion of the encapsulant, such as, for example, to at least about 40 percent by weight gel content, preferably at least about 55 percent by weight gel content and more preferably at least about 70 percent by weight gel content.

According to one embodiment, the step of laminating includes the use of vacuum or reduced pressure to remove and/or displace air, moisture, other volatiles and/or any other less desirable material from the solar panel. Desirably, the laminating step creates intimate contact between adjacent portions or parts of the solar panel, such as, for example, to improve thermal conductivity and improve integrity by reducing bubbles.

According to one embodiment, desirably, but not necessarily, the first sheet of encapsulant material differs from the second sheet of encapsulant material. According to another embodiment, desirably, but not necessarily, the first sheet of encapsulant material does not differ from the second sheet of encapsulant material. Other configurations are possible.

According to one embodiment, the solar panel does not include a front sheet of encapsulant, but a single back sheet of encapsulant provides adequate lamination for the solar panel. Alternately, according to another embodiment, the solar panel does not include a back sheet of encapsulant, but a single front sheet of encapsulant provides adequate lamination of the solar panel. According to another embodiment, a sheet of encapsulant includes holes, cuts and/or punch outs around at least a portion of the solar cells and/or wiring. According to yet another embodiment, the backsheet includes sufficient encapsulating capabilities to eliminate the separate second or back layer of encapsulant from the solar panel. According to still a further embodiment, a single backsheet provides adequate lamination for the solar panel with the exclusion of all additional sheets and/or forms of encapsulants. Furthermore, additional layers of materials within and/or on the solar panel are possible.

According to one embodiment, the solar or photovoltaic cell and/or panel of this invention may operate at least about 0.5 degrees Celsius cooler in direct overhead sunlight compared to a conventional solar or photovoltaic cell and/or panel (nonfilled encapsulant and nonfilled backsheet) of similar construction and operating in similar conditions, at least about 1.0 degrees Celsius cooler in direct overhead sunlight compared to a conventional solar or photovoltaic cell and/or panel of similar construction and operating in similar conditions, at least about 2.0 degrees Celsius cooler in direct overhead sunlight compared to a conventional solar or photovoltaic cell and/or panel of similar construction and operating in similar conditions, at least about 3.0 degrees Celsius cooler in direct overhead sunlight compared to a conventional solar or photovoltaic cell and/or panel of similar construction and operating in similar conditions, at least about 4.0 degrees Celsius cooler in direct overhead sunlight compared to a conventional solar or photovoltaic cell and/or panel of similar construction and operating in similar conditions, at least about 5.0 degrees Celsius cooler in direct overhead sunlight compared to a conventional solar or photovoltaic cell and/or panel of similar construction and operating in similar conditions, at least about 7.0 degrees Celsius cooler in direct overhead sunlight compared to a conventional solar or photovoltaic cell and/or panel of similar construction and operating in similar conditions, at least about 10.0 degrees Celsius cooler in direct overhead sunlight compared to a conventional solar or photovoltaic cell and/or panel of similar construction and operating in similar conditions, and/or the like.

Direct overhead sunlight broadly refers to a peak intensity of solar radiation, such as a local time of day between about 10:00 A.M. and about 3 P.M., between about 11:00 A.M. and 2:00 P.M., about 12:00 P.M., and/or the like. Other factors affecting solar radiation may include stratospheric ozone level, time of year, latitude, altitude, weather conditions, and/or the like.

According to one embodiment, the solar or photovoltaic cell and/or panel of this invention may produce at least about 0.5 percent more power in direct overhead sunlight compared to a conventional solar or photovoltaic cell or photovoltaic and/or panel (nonfilled encapsulant and nonfilled backsheet) of similar construction and operating in similar conditions, at least about 1.0 percent more power in direct overhead sunlight compared to a conventional solar or photovoltaic cell and/or panel of similar construction and operating in similar conditions, at least about 1.5 percent more power in direct overhead sunlight compared to a conventional solar or photovoltaic cell and/or panel of similar construction and operating in similar conditions, at least about 2.0 percent more power in direct overhead sunlight compared to a conventional solar or photovoltaic cell and/or panel of similar construction and operating in similar conditions, at least about 3.0 percent more power in direct overhead sunlight compared to a conventional solar or photovoltaic cell and/or panel of similar construction and operating in similar conditions, at least about 4.0 percent more power in direct overhead sunlight compared to a conventional solar or photovoltaic cell and/or panel of similar construction and operating in similar conditions, at least about 5.0 percent more power in direct overhead sunlight compared to a conventional solar or photovoltaic cell and/or panel of similar construction and operating in similar conditions, and/or the like.

According to one embodiment of this invention, the backsheet includes additional fins, ridges, heat sinks and/or extended surfaces to promote and/or aid in additional heat transfer. According to another embodiment, the solar panel further includes a plurality of metal fins, ridges, heat sinks and/or extended surfaces thermally coupled with the backsheet. One or more additional convection devices may also be included, such as, for example, fans and/or blowers. Peltier coolers, thermoelectric coolers, thermionic coolers and/or other similar devices may also be added to facilitate heat removal from the solar panel. Alternately, the use of liquid coolers, refrigeration cycles and/or heat engines may provide additional mechanisms for removal of heat or temperature from a solar panel to improve efficiencies.

### EXAMPLES

### Comparative Example 1

To test the effectiveness of the filled encapsulant according to one embodiment, a reference sample laminated panel was prepared according to known conventional practices. The panel included a single square solar cell with a length and a width of 156 millimeters laminated to a single square piece of glass with a length and a width of 203 millimeters. The solar cell was laminated to the glass with a fast cure ethylene vinyl acetate having other known additives. The back side of the solar cell was laminated with a fast cure ethylene vinyl acetate and glass scrim material. The laminated panel excluded a back sheet.

To probe the temperature on the back of the solar cell in the solar panel, a cement-on E-type thermocouple (CO2-E) from Omega Engineering, Inc, Stamford, Conn., U.S.A. was used. The thermocouple was connected to the backside of the solar cell of the solar panel in the following manner. First, a polyimide film tape, 3M #5413, from 3M Company, St Paul, Minn., U.S.A. was applied to a central portion of the backside of the solar cell. The cement-on E-type thermocouple was then attached to the film tape non-stick surface by using a second layer of the polyimide film tape on the surface of the thermocouple. The thermocouple was connected to a Fluke data acquisition and logging device from Fluke Corporation, Everett, Wash., U.S.A. The laminated panel was connected to a circuit including a 3900 ohm resistor. Voltage was also recorded. The laminated panel was mounted on rails to a backing board. The backing board was exposed to several days of operation as further discussed below. The data acquisition rate was every 20 seconds or 3 times a minute. The data represents late fall days taken at a test site located in Frederick, Md., U.S.A.

### Example 1

A laminated panel was prepared according to comparative Example 1 above except the back side encapsulant was replaced with an ethylene vinyl acetate filled with 15 weight percent silicon carbide having an average particle size of 9 micrometers. The encapsulant did not include glass scrim. The silicon carbide containing panel was outfitted with a thermocouple and mounted to the backing board as above. The data acquisition and data logging apparatus was configured to record the temperature and voltage of the panel with the silicon carbide filled encapsulant.

The time of day versus differences (reference minus filled EVA) of the temperatures measured by the respective thermocouples are shown in FIGS. 4-6. FIG. 4 shows the temperature difference being relatively small (less than about 1 degree Celsius) during the early morning and the late afternoon. The temperature difference peaked around noon time at about 5 degrees Celsius.

FIG. 5 shows data on a different day with the same solar panels. The temperature difference in the afternoon period ranged from about 3 degrees Celsius to about 7 degrees Celsius. It is believed that some of the variability in the graph is created by shifting overhead clouds. The temperature difference decreased late afternoon as the angle of the sun decreased.

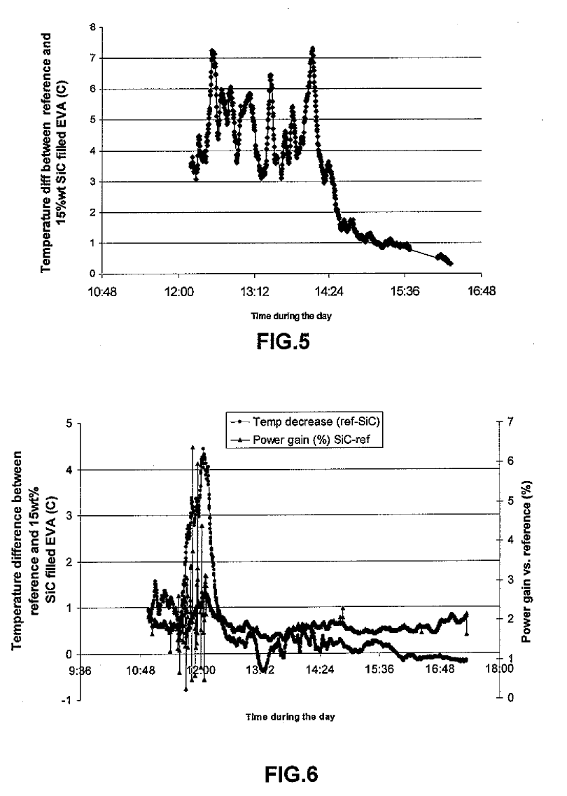

FIG. 6 shows data on a still different day with the same solar panels. The temperature difference in the early afternoon peaked at over 4 degrees Celsius and tapered off during later afternoon when the sun was no longer directly overhead. The difference in the power was calculated by squaring the measured voltage and dividing by the resistance value. The difference in power increased as a percentage of the reference power proportional to the increase in temperature difference. The power increase ranged between about 1 percent to over 6 percent (at noon).

### Example 2

A second laminated panel was prepared according to comparative Example 1 above except the back side encapsulant was replaced with an ethylene vinyl acetate filled with 15 weight percent talc having a mean particle size of 1.5 micrometers. The encapsulant did not include glass scrim. The talc containing panel was outfitted with a thermocouple and mounted to the backing board as above. The data acquisition and data logging apparatus was configured to record the temperature and voltage of the panel with the talc filled encapsulant.

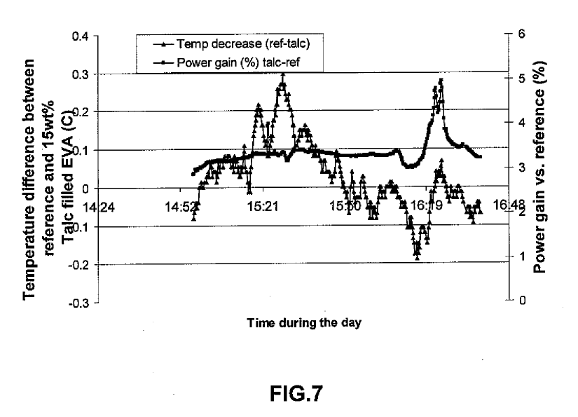

FIG. 7 shows data on a still different day with the reference and the talc filled encapsulant panel. The temperature difference peaked earlier in the afternoon and continued to decline with changes in overhead sun. The difference in power averaged over 3 percent. The power difference may be overstated due at least in part to the resistor size.

While in the foregoing specification this invention has been described in relation to certain preferred embodiments, and many details are set forth for purpose of illustration, it will be apparent to those skilled in the art that this invention is susceptible to additional embodiments and that certain of the details described in this specification and in the claims can be varied considerably without departing from the basic principles of this invention.

What is claimed is:

1. A photovoltaic or semiconductor encapsulant, the encapsulant comprising:
a polymeric material; and
a filler material;
wherein the encapsulant has a thermal conductivity of about at least 0.26 watt per meter per Kelvin and a dielectric constant of about at least 2.0 measured at 60 hertz.

2. The encapsulant of claim 1, wherein the polymeric material is selected from the group consisting of ethylene vinyl acetate, polyurethane, polysilicone, polypropylene, polyethylene ionomers and combinations thereof.

3. The encapsulant of claim 1, wherein the polymeric material comprises a copolymer of ethylene and vinyl acetate including about 4 percent to about 90 percent vinyl acetate by weight.

4. The encapsulant of claim 1, wherein the filler material comprises glass fibers.

5. The encapsulant of claim 1, wherein the encapsulant comprises the filler material from about 0.1 percent to about 30 percent by volume.

6. The encapsulant of claim 1, further comprising at least one silane coupling agent for dispersing the filler material in the polymeric material or promoting adhesion of the encapsulant to other materials of a photovoltaic or a semiconductor.

7. The encapsulant of claim 6, wherein the at least one silane coupling agent comprises:
a first reactivity type selected from the group consisting of amino groups, epoxy groups, phenyl groups, vinyl groups, alkyl groups; and
a second reactivity type selected from the group consisting of methoxy reactivity groups, ethoxy reactivity groups and combinations thereof.

8. The encapsulant of claim 1, wherein the filler material is selected from the group consisting of aluminum nitride, calcium carbonate, calcium silicate, talc, barite, clay, titanium oxide, magnetite, aluminum oxide, silicon dioxide, boron nitride, silicon carbide and combinations thereof.

9. The encapsulant of claim 1, wherein the filler material has an average particle size of about 0.001 micrometers to about 1000 micrometers.

10. The encapsulant of claim 1, wherein the encapsulant forms pellets for additional processing.

11. The encapsulant of claim 1, wherein the encapsulant forms sheets or films.

12. The encapsulant of claim 1, wherein the filler material has an aspect ratio of equal to or greater than about 1.

13. The encapsulant of claim 1, wherein the filler material has an aspect ratio of at least about 5.

14. The encapsulant of claim 1, wherein the polymeric material comprises a chemical crosslinking agent.

15. The encapsulant of claim 1, wherein the encapsulant comprises a thermal diffusivity of at least 1.3×10⁻⁷ meters squared per second.

16. The encapsulant of claim 1, wherein the thermal conductivity is measured at 30 degrees Celsius.

17. A photovoltaic or semiconductor backsheet, the backsheet comprising:
a polymeric material; and
a filler material;
wherein the backsheet has a dielectric constant of about at least 2.0 measured at 60 hertz and a higher thermal conductivity than the polymeric material in neat form.

18. The backsheet of claim 17, where the polymeric material is selected from the group consisting of polypropylene, polyethylene terephthalate, polyvinyl fluoride, polyvinylidene fluoride, polytetrafluoroethylene and combinations thereof.

19. The backsheet of claim 17, further comprising additional laminated layers including polyester, aluminum, polyvinyl fluoride, polyvinylidene fluoride and combinations thereof.

20. The backsheet of claim 17, wherein the backsheet comprises a multilayer material selected from the group consisting of polyvinyl fluoride-polyester-polyvinyl fluoride, polyvinyl fluoride-aluminum-polyvinyl fluoride, polyvinyl fluoride-aluminum-polyester, polypropylene, polyethylene terephthalate, polyvinyl fluoride, polyvinylidene fluoride, polytetrafluoroethylene and combinations thereof.

21. The backsheet of claim 17, wherein the filler material is selected from the group consisting calcium carbonate, calcium silicate, talc, barite, clay, rutile titanium oxide, anatase titanium oxide, magnetite, alumina, silicon dioxide, aluminum nitride, boron nitride, silicon carbide and combinations thereof.

22. A solar panel comprising a front layer and at least one photovoltaic cell, the panel comprising:
the front layer disposed with respect to a front side of the at least one photovoltaic cell;
an encapsulant contacting at least a portion of a back side of the at least one photovoltaic cell and disposed at least partially between the at least one photovoltaic cell and a backsheet, the encapsulant comprising a first polymeric material and a first thermal conducting filler material, the encapsulant having a thermal conductivity of about at least 0.26 watt per meter per Kelvin and a dielectric constant of about at least 2.0 measured at 60 hertz; and
the backsheet.

23. The solar panel of claim 22, wherein the backsheet comprises a second polymeric material and a second thermal conducting filler material, the backsheet having a dielectric constant of about at least 2.0 measured at 60 hertz and a higher thermal conductivity than the second polymeric material in neat form.

24. A solar panel of claim 22, wherein the backsheet comprises a glass sheet with a thermal conductivity of at least about 1.4 watt per meter per Kelvin.

25. The solar panel of claim 23, wherein:
the first polymeric material comprises ethylene vinyl acetate; and the second polymeric material comprises polyethylene terephthalate.

26. The solar panel of claim 25, wherein the ethylene vinyl acetate comprises a copolymer of ethylene and vinyl acetate having about 4 percent to about 90 percent by weight vinyl acetate and a melt flow index of about 5 to about 40 grams per 10 minutes.

27. The solar panel of claim 22, further comprising at least one solar concentrator.

28. The solar panel of claim 22, wherein the at least one photovoltaic cell operates at least about 2.0 degrees Celsius cooler in direct overhead sunlight compared to a conventional photovoltaic cell or panel and operating in similar conditions.

29. The solar panel of claim 22, wherein the at least one photovoltaic cell produces at least about 0.5 percent more power in direct overhead sunlight compared to a conventional photovoltaic cell or panel and operating in similar conditions.

30. A process for making a solar panel comprising:
providing a front layer;
placing a first sheet of encapsulant material over at least a portion of the front layer;
placing at least one photovoltaic cell over the first sheet of encapsulant material;
placing a second sheet of encapsulant material over the at least one photovoltaic cell, the second sheet of encapsulant material comprising a first polymeric material and a first filler material, the second sheet of encapsulant material having a thermal conductivity of about at least 0.26 watt per meter per Kelvin and a dielectric constant of about at least 2.0 measured at 60 hertz;
placing a backsheet over the second sheet of encapsulant material, the backsheet comprising a second polymeric material and a second filler material, the backsheet having a dielectric constant of about at least 2.0 and a higher thermal conductivity than the second polymeric material in neat form; and
laminating the solar panel for a sufficient time and a sufficient temperature for sufficient crosslinking of the first sheet or the second sheet.

31. The process of claim 30, wherein laminating uses a vacuum to remove from the solar panel one selected from the group consisting of air, moisture, other volatiles and combinations thereof.

32. The process of claim 30, wherein the first sheet of encapsulant material differs from the second sheet of encapsulant material.
